(19) United States
(12) Patent Application Publication
(10) Pub. No.: US 2010/0258246 A1
(43) Pub. Date: Oct. 14, 2010

(54) Plasma Processing System

(76) Inventors: Takehisa Iwakoshi, Odawarashi (JP); Masaru Izawa, Tokyo (JP); Akira Kagoshima, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/511,220

(22) Filed: Jul. 29, 2009

(30) Foreign Application Priority Data
Apr. 10, 2009 (JP) JP 2009-096052

(51) Int. Cl. H01L 21/3065

(52) U.S. Cl. 156/345.24

(57) ABSTRACT

A plasma processing system includes a processing chamber provided with a plasma generation unit for applying radio-frequency power to supplied processing gas to generate plasma and a stage for holding workpieces, and a control computer for generating plasma in accordance with preset processing conditions to sequentially apply plasma processing to the workpieces and also for sequentially collecting system parameter values each of which represents a state of the plasma processing. The computer is provided with a record unit for storing, in every predetermined period, a frequency that each of the collected system parameter values deviates from a preset reference value, an occurrence rate calculation unit for calculating, based on the frequency, an occurrence rate that the each of the system parameter values deviates from the reference value, and a comparison unit for comparing the occurrence rate with a preset reference value to diagnose a state of the system.

### CROSS-REFERENCE TO RELATED APPLICATION

This application claims the priority of Japanese Patent Application 2009-096052 filed Apr. 10, 2009, which is incorporated herein by reference.

### BACKGROUND OF THE INVENTION

1. Field of the Invention

This invention relates to a plasma processing system, and especially to a plasma processing system capable of diagnosing its state on the basis of acquired parameter values.

2. Description of the Related Art

To form microcircuits or microelectron devices on a surface of a semiconductor wafer or the like, plasma processing such as plasma etching is used. As a high fabrication yield is required for a fabrication process of semiconductor devices, there is an outstanding desire for a technology that makes it possible to detect a sign before the occurrence of a disastrous processing abnormality. In the event of occurrence of an abnormality in a plasma processing system, it is also desired to achieve restoration in a short time from the standpoint of improved fabrication throughput.

As technologies for detecting a sign before the occurrence of a disastrous processing abnormality, JP-A-2004-131777 discloses a method that detects abnormal discharges of plasma and performs control of workpieces on the basis of the frequency of the abnormal discharges. JP-A-2004-200323 discloses a method that, when processing abnormalities take place in succession, interrupts processing by estimating that a plasma processing system is in a disastrously abnormal state. Further, JP-A-2006-324316 discloses a method that collects system parameter values of a plasma processing system and diagnoses that the plasma processing system is abnormal if any system parameter value differs from the corresponding system parameter value when the plasma processing system is normal.

### SUMMARY OF THE INVENTION

In plasma processing, however, a method that sets a distinct threshold between an abnormality and a normality as in JP-A-2004-131777 generally does not work well, because fluctuations always exist in processing conditions, thereby unavoidably resulting in such an erroneous determination that normal processing may be determined to be abnormal or abnormal processing may be determined to be normal.

Especially when an extremely minute foreign object is caught between a workpiece and a stage on which the workpiece is held, an abnormal state is detected in terms of a parameter of a processing system in many instances although the processing itself is completed as normally. In such a case, the processing system is determined to be abnormal although the processing has been completed normally. The processing is hence stopped, leading to a reduction in the operation rate of the system.

In view of such a drawback, JP-A-2004-200323 stops processing only when processing abnormalities take place in succession. However, the above-mentioned fluctuations mean the existence of such a situation that after abnormal processing, the processing once becomes normal and then becomes abnormal again. Therefore, a malfunction of the processing system may be overlooked insofar as only successive abnormalities are detected as abnormalities.

It is, therefore, a common practice to use the method that, as disclosed in JP-A-2006-324316, collects processing parameters to determine whether processing is abnormal or normal. Mere collection of parameter values, however, cannot ascertain a cause of an abnormality in many instances, because plural processing parameters generally turn out to be abnormal values when a processing abnormality occurs. In such a situation, the experience and intuition of a skilled engineer have to be relied upon in many instances to ascertain the cause of the abnormality, thereby making it difficult to take a quick countermeasure.

With these problems in view, the present invention has as an object the provision of a plasma processing system which makes it possible to detect the occurrence of an abnormality in the system with high accuracy and further to readily search for a cause of the abnormality.

To achieve the above-described object, the present invention provides a plasma processing system comprising:

a processing chamber provided with a plasma generation unit for applying radio-frequency power to supplied processing gas to generate plasma and a stage for holding workpieces thereon, and

a control computer for generating plasma in accordance with preset processing conditions to sequentially apply plasma processing to the workpieces held on the stage and also for sequentially collecting system parameter values each of which represents a state of the plasma processing,

wherein the control computer is provided with:

a record unit for storing, in every predetermined period, a frequency that each of the collected system parameter values deviates from a preset reference value,

an occurrence rate calculation unit for calculating, based on the frequency, an occurrence rate that the each of the system parameter values deviates from the reference value, and

a comparison unit for comparing the occurrence rate with a preset reference value to diagnose a state of the system.

Owing to the constitution described above, the plasma processing system according to the present invention makes it possible to detect the occurrence of an abnormality in the system with high accuracy and further to readily search for a cause of the abnormality.

### BRIEF DESCRIPTION OF THE DRAWINGS

FIG. 1 is a block diagram illustrating the construction of a plasma processing system according to a first embodiment of the present invention.

FIG. 2 is a block diagram illustrating details of a control computer in the plasma processing system according to the first embodiment of the present invention.

FIG. 3 is a block diagram illustrating the control computer of FIG. 2, which is additionally equipped with a model-equation derivation unit.

FIG. 4 is a diagram showing differences between a calculated value and found values (experimental values) of a processing parameter.

FIG. 5 is a diagram showing occurrence rates of the determination of an abnormality in predetermined periods.

FIG. 6 is an association diagram showing an illustrative output from a schematization unit.

FIG. 7 is an association diagram showing an example in which a cause of an abnormality in the system is diagnosed and visualized.

FIG. 8 is a diagram showing variations with time in a supply rate of heat-conducting gas to be supplied to a stage.

FIG. 9 is a block diagram illustrating details of a control computer in a plasma processing system according to a second embodiment of the present invention.

FIG. 10 is a block diagram illustrating the control computer of FIG. 9, which is additionally equipped with a model-equation derivation unit.

FIG. 11 is a diagram showing variations with time in a mode value of differences between a calculated value and found values (experimental values) of a processing parameter.

FIG. 12 is a diagram showing variations with time in a supply rate (found value) of heat-conducting gas and also variations with time in a mode value of supply rates (found values) of the heat-conducting gas.

FIG. 13 is a diagram describing respective parameter names shown in FIGS. 6 and 7 and their meanings.

### DETAILED DESCRIPTION OF PREFERRED EMBODIMENTS

### First Embodiment

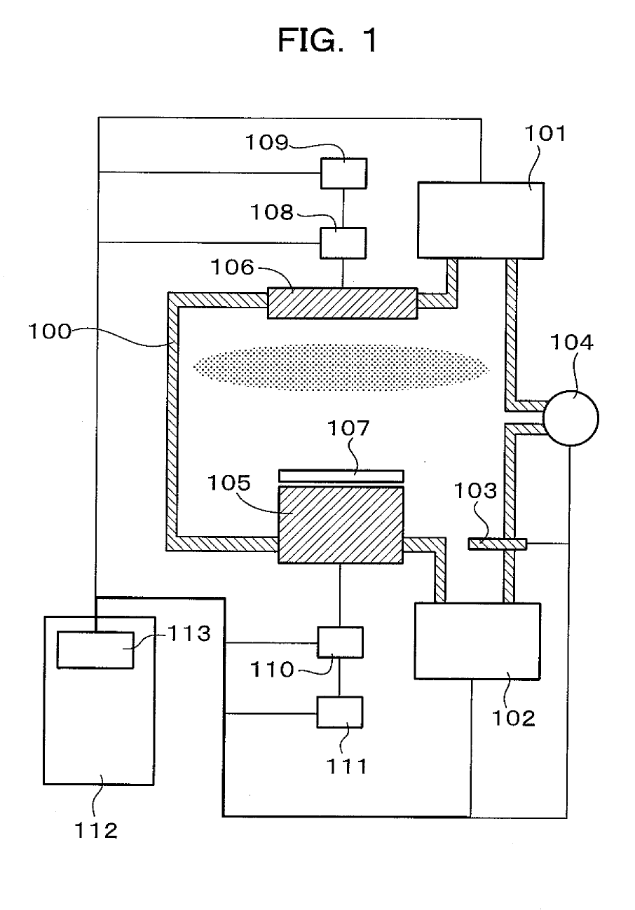

The plasma processing system according to the first embodiment will hereinafter be described with reference to FIGS. 1 through 8 of the accompanying drawings. In FIG. 1, a plasma processing chamber 100 for processing workpieces is provided with a gas supply unit 101 for supplying processing gas, a valve 103 and gas exhaust unit 102 for adjusting evacuation of the processing gas to control a pressure inside the plasma processing chamber 100, and a pressure gauge 104 for measuring the pressure within the plasma processing chamber 100. The plasma processing chamber 100 is also provided with a plasma generation unit 106 for generating plasma, and the plasma generation unit 106 is provided with a radio-frequency (hereinafter abbreviated as “RF”) power source 109 for supplying power to the plasma generation unit 106 and a tuner 108 for adjusting the impedance of a power supply line between the RF power source 109 and the plasma generation unit 106.

Arranged inside the plasma processing chamber 100 is stage 105 for holding a workpiece thereon. The stage 105 is provided with an RF power source 111 for applying a voltage to the stage and a tuner 110 for adjusting the impedance of a power supply line between the RF power source 111 and the stage 105. It is to be noted that, when plasma is generated by using electron cyclotron resonance, a coil is arranged as an electromagnet around the plasma processing chamber 100.

The plasma processing system of this embodiment is also provided with a control computer 112, and the control computer 112 is provided with a processing parameter acquisition unit 113 for acquiring processing parameters such as the indicated pressure value of the pressure gauge 104, the opening degree of the valve 103, the output power values of the RF power sources 109,111, the impedance values and reflected power values detected by the tuners 108,110.

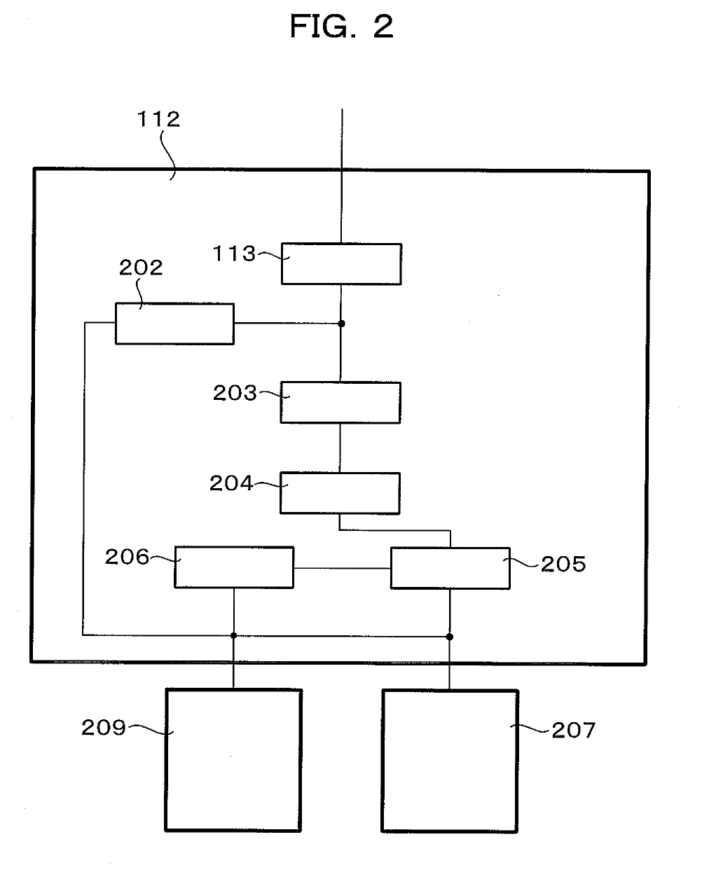

Reference is next had to FIG. 2. As mentioned above, the control computer 112 is provided with the processing parameter acquisition unit 113, and transmits received processing parameters to a schematization unit 202, which schematizes causal associations among the processing parameters, and also to a first comparison unit 203.

The schematization unit 202 schematizes the causal associations among the processing parameters so received, and shows them on a display unit 209. As a schematization method, a known method such as the SGS algorithm, WL algorithm, PC algorithm, Dempster's covariance selection, graphical modeling or multivariate analysis can be used.

The first comparison unit 203 determines whether or not a value of each processing parameter deviates from a predetermined output range (first reference value). The value of the processing parameter is determined to be abnormal when it deviates from the first reference value, but is determined to be normal when it does not deviate from the first reference value.

The determination made by the first comparison unit 203 as described above is stored as history in the record unit 204. Based on the history stored in the record unit 204, an occurrence rate calculation unit 205 calculates an occurrence rate that the determination of an abnormal value was made in a predetermined period.

The value of the occurrence rate, which has been calculated by the occurrence rate calculation unit 205, is delivered to a second comparison unit 206, and is compared with a predetermined second reference value to determine whether or not the value of the occurrence rate is not smaller than the second reference value. When the value of the occurrence rate is not smaller than the second reference value, an alarm is given by an alarm unit 207 to the effect that the plasma processing system is in an abnormal state. In addition, the results of calculations by the control computer 112 are shown on the external display unit 209.

A description will next be made about the predetermined output range (first reference value) to be compared with each value of the processing parameter at the first comparison unit. This output range is a range indicating that the system is operating normally. It is, therefore, desired to statistically determine the output range from the record of previous processing data. Versatility will, however, be lost if the output range is separately determined for respective different processing conditions.

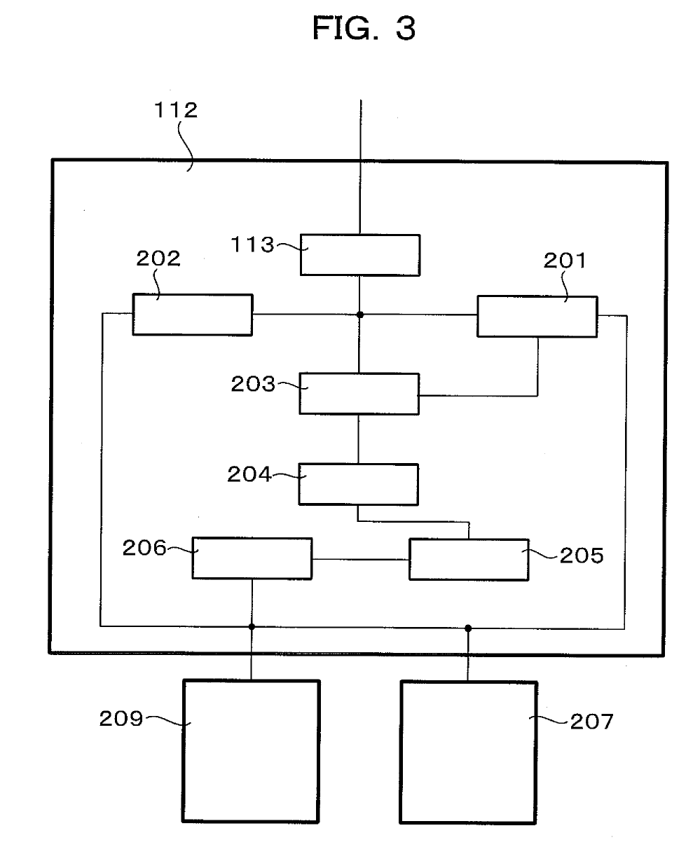

Referring to FIG. 3, a description will be made about the control computer 112 additionally provided with a model-equation derivation unit 201 that produces standard values (model values) of the processing parameters. The model-equation derivation unit 201 converts correlations of the respective processing parameters into model equations such that standard values can be produced for desired ones of the processing parameters. When relations between values of desired one of the processing parameters and values of the remaining processing parameters are approximately expressed by a linear multivariable function, for example, it is possible to calculate values (model values) of the remaining processing parameters which the normal system can inherently have relative to each value of the desired processing parameter.

As the ranges of normal values of the respective processing parameters can be calculated by the control computer 112 as described above, the reference values to be used at the first comparison unit 203 can be flexibly determined by using the ranges so that the versatility of the system can be improved further.

The ranges of values of the respective processing parameters, which the normal system can inherently have, can be determined, for example, by statistically investigating the departures of found values of the respective processing parameters from their corresponding model values. Determination of the above-described reference ranges on the basis of the thus-determined ranges is very convenient because desired conditions of the normal system can be dealt with. It is to be noted that, although the above description is directed to the method that approximately expresses by the linear multivariable function the relations between values of the desired one of the processing parameters and values of the remaining processing parameters, the model equation for the relations may of course be expressed by a different method which presumes a nonlinear function or the like.

In FIG. 3, the processing parameters acquired by the processing parameter acquisition unit 113 are transmitted to the model-equation derivation unit 201, schematization unit 202 and first comparison unit 203.

Based on the thus-received processing parameters, the model-equation derivation unit 201 derives a model equation that expresses responses of the desired processing parameter to the group of the remaining processing parameters. The model-equation derivation unit 201 then transmits response values (calculated values), which have been obtained by the thus-derived model equation, to the first comparison unit 203. The first comparison unit 203 compares each processing parameter (found value) so received with its corresponding response value (calculated value) obtained by the model equation, and calculates the difference between them, the absolute value of the difference, the square of the difference, or the like to determine the degree of a divergence of the processing parameter value from its corresponding response value obtained by the model equation. Subsequently, a determination is made based on the degree of the divergence as to whether or not the processing parameter value deviates from the corresponding response value obtained by the model equation. The processing system is determined to be normal when the processing parameter does not deviate, but is determined to be abnormal when the processing parameter deviates.

The above-described determination made by the first comparison unit 203 is transmitted to the record unit 204, and the record unit 204 stores the determination so received. Subsequent operations are the same as in the case illustrated in FIG. 2.

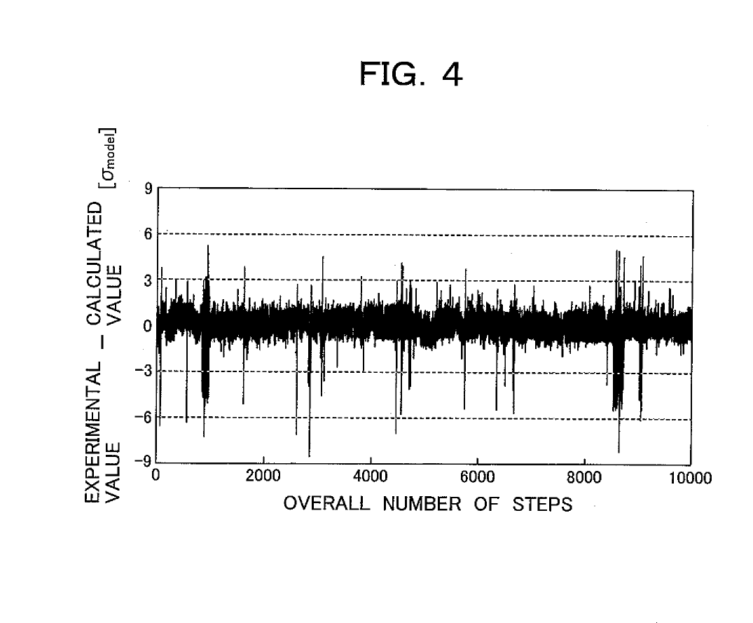

The diagram of FIG. 4 shows the differences between the calculated value of the desired processing parameter and its corresponding found values (experimental values) as calculated by the first comparison unit 203. Relative to the overall number of processing steps plotted along the abscissa, the differences between the calculated value of the desired processing parameter and its corresponding found values, which are plotted along the ordinate, behave substantially like white noise.

If a threshold is set (for example, a variance σ_{model} is calculated with respect to the departures from the response value obtained by the model equation and the threshold is set at 3σ_{model}) and a rule is made such that the state of the system is diagnosed to be abnormal when the absolute value of the difference between the calculated value and a found value of the processing parameter exceeds the threshold, an alarm that the plasma processing system is in an abnormal state is hence produced frequently. In such a situation, a normal state is erroneously determined to be an abnormal state, thereby not only lowering the operation rate of the system but also impairing the reliability of the alarm. It is to be noted that, if the threshold is set large, no abnormality can be detected even when the plasma processing system falls in a truly abnormal state.

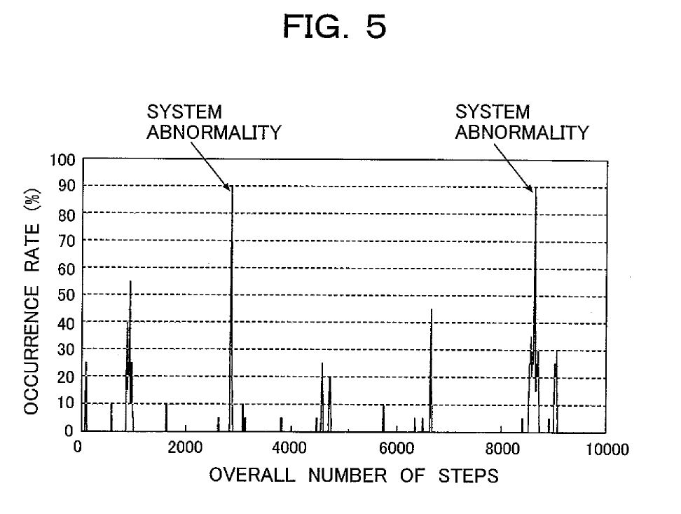

In the diagram of FIG. 5, occurrence rates that, in predetermined periods (for example, during past 20 steps), a determination of abnormality is made are plotted along the ordinate. Such a diagram is obtained by the occurrence rate calculation unit 205. Since the differences between a calculated value and found values of a processing parameter are substantially like white noise as mentioned above, the rate (%) that the determination of abnormality is made is low when the plasma processing system is in a normal state. When the plasma processing system falls in a truly abnormal state, however, the rate (%) that the determination of abnormality is made increases. Accordingly, the reliability of an alarm can be heightened. In FIG. 5, the system is defined to be in a truly abnormal state when the rate (%) that the determination of abnormality is made exceeds 60%. At this setting, it was possible to detect, with high accuracy, each state that the system was in a truly abnormal state. With respect to each of the remaining processing parameters, similar processing is performed to determine whether the plasma processing system is in a normal or abnormal state.

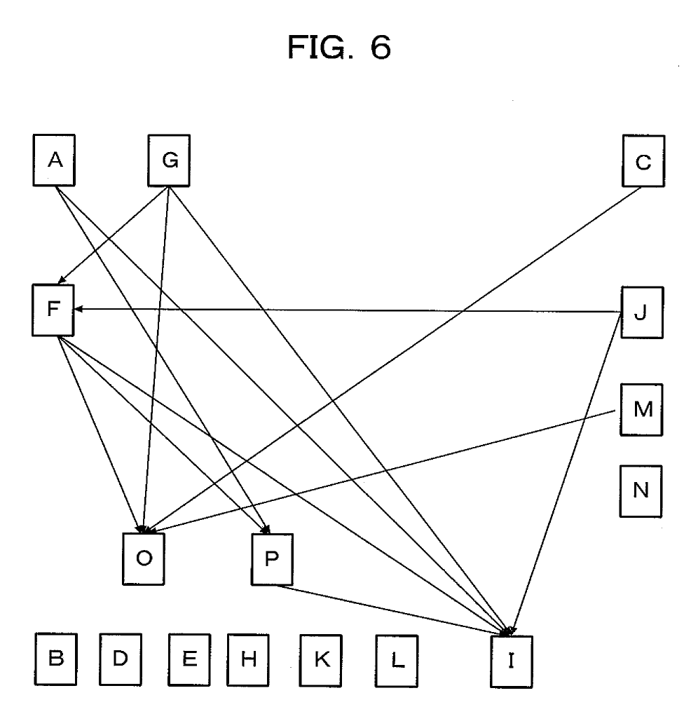

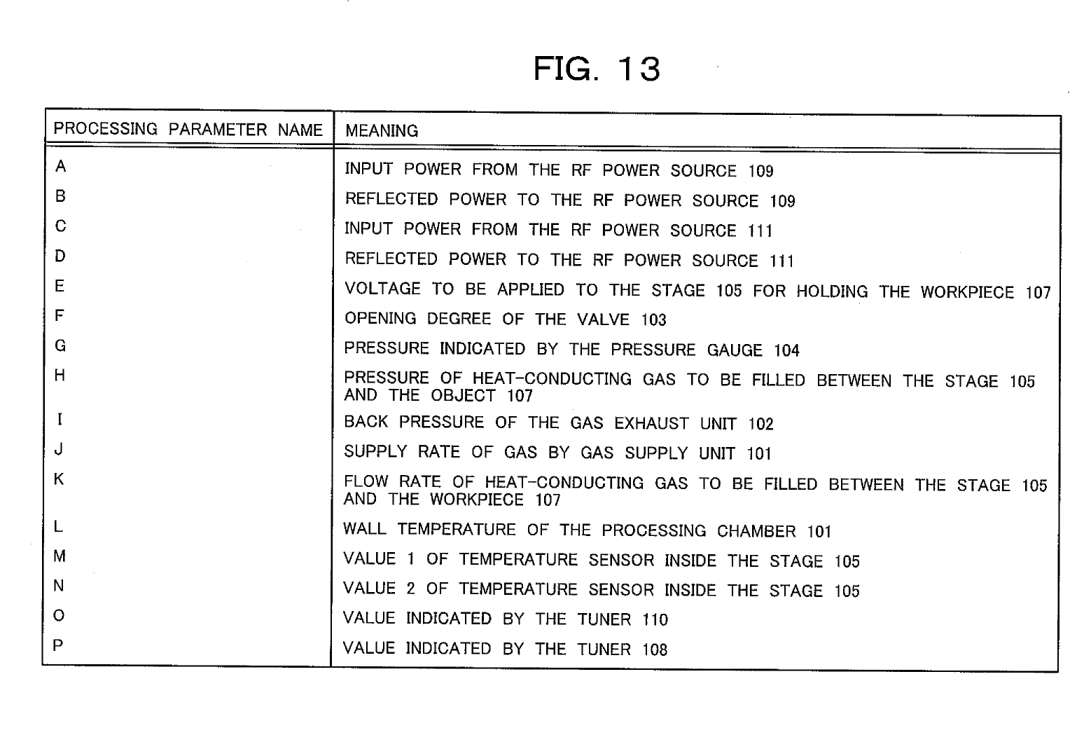

The association diagram of FIG. 6 illustrates an output from the schematization unit 202 that outputs the causal associations among the processing parameters. The processing parameters signs shown in FIG. 6 have the meanings summarized in FIG. 13. The arrows in FIG. 6 each indicate that the tail is a cause and the head is an effect.

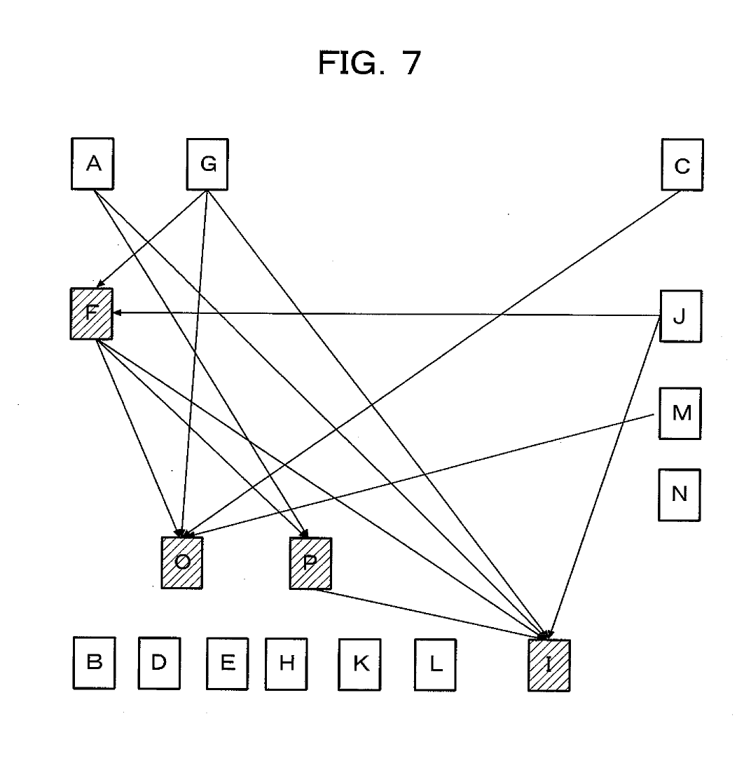

The association diagram of FIG. 7 illustrates an output from the schematization unit 202 that outputs the causal associations among the processing parameters. The processing parameters signs and arrows shown in FIG. 7 have the same meanings as those shown in FIG. 6. In FIG. 7, the processing parameters (F, O, P, I) that the differences between the calculated values obtained by the model equation and their corresponding found values exceeded their corresponding thresholds are highlighted by hatching. In addition to the parameter (F), the found values of the other parameters (O, P, I) each of which is in a causal association with the parameter (F) deviate from their corresponding calculated values obtained by the model equation, and are abnormal values. By tracing back the causal associations, however, it can be readily estimated that the parameter (F) (the opening degree of the valve 103) is the cause of the abnormal state of the plasma processing system.

By schematizing the causal associations among the processing parameters as described above, the cause of an abnormal state of the plasma processing system can be readily estimated so that the maintenance time can be shortened. It is also possible to facilitate the visual recognition of the cause of the abnormal state by highlighting one or more parameters, the found values of which deviated from the corresponding reference ranges, in a color or pattern different from the normal processing parameters as in FIG. 7.

As one example of abnormality detection, a description will be made of an estimation method for the time of replacement of the stage 105. In the plasma processing system, the workpiece is heated by plasma. A cooling unit is, therefore, arranged inside the stage 105 for cooling the workpiece 107. Upon cooling, heat-conducting gas having high thermal conductive properties, such as helium, is filled between the workpiece 107 and the stage 105 to increase the thermal conductivity. When the stage 105 and the workpiece 107 are in close contact with each other, the heat-conducting gas practically does not leak out so that its supply rate can be kept low. Once the surface of the stage 105 begins to wear off, the heat-conducting gas leads out through the resulting clearance so that the required supply rate of the gas increases. It is, therefore, possible to recognize the wear conditions of the stage 105 by monitoring the supply rate of the gas.

If an extremely minute foreign object is caught between the stage 105 and the work piece 107, the heat-conducting gas may leak out. In other words, there is a situation that the required supply rate of the heat-conducting gas increases even when the wearing of the stage 105 has not progressed much.

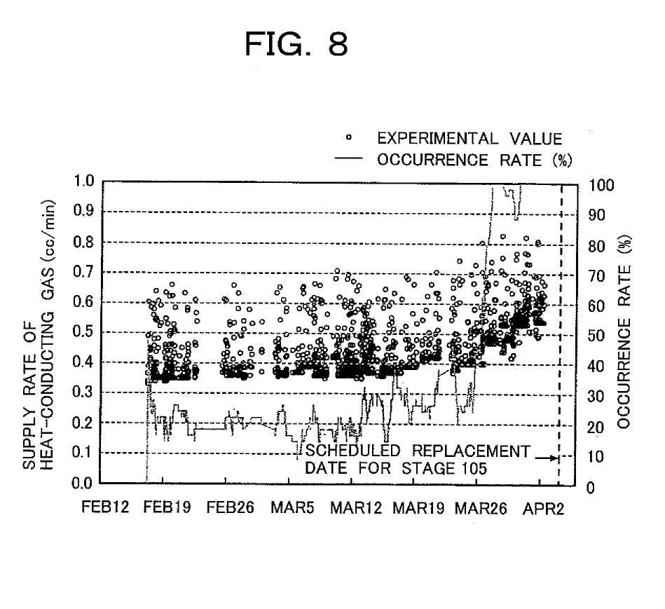

The diagram of FIG. 8 shows variations with time of the supply rate of heat-conducting gas to be supplied to the stage. It can be appreciated that, as shown in the diagram, the actual value of the supply rate of the heat-conducting gas increases as variations of the stage 105 progress with time and the time for replacement of the stage 105 is approached. It can also be observed that the supply rate occasionally undergoes a sudden increase before the progress of variations of the stage 105. It is also evident from the diagram that any attempt to detect the time for replacement of the stage 105 by setting a threshold with respect to the supply rate does not work well under such a situation.

When the occurrence rate of the found values greater than the preset reference value is calculated, on the other hand, the results of the calculation become similar to the curve shown in FIG. 8. When the occurrence rate has exceeded 60% in this example, the time for replacement can be readily notified by producing an alarm from the alarm unit 207 such that the replacement of the stage 105 is urged.

As has been described above, the first embodiment of the present invention calculates the occurrence rate of a situation that a collected value of a system parameter deviates from the corresponding preset reference range, and compares the thus-calculated occurrence rate with its corresponding preset reference value to diagnose the state of the system. It is, therefore, possible to produce a high-reliability alarm for an abnormality of the system. Further, the use of the resulting association diagram makes it possible to promptly find out the cause.

### Second Embodiment

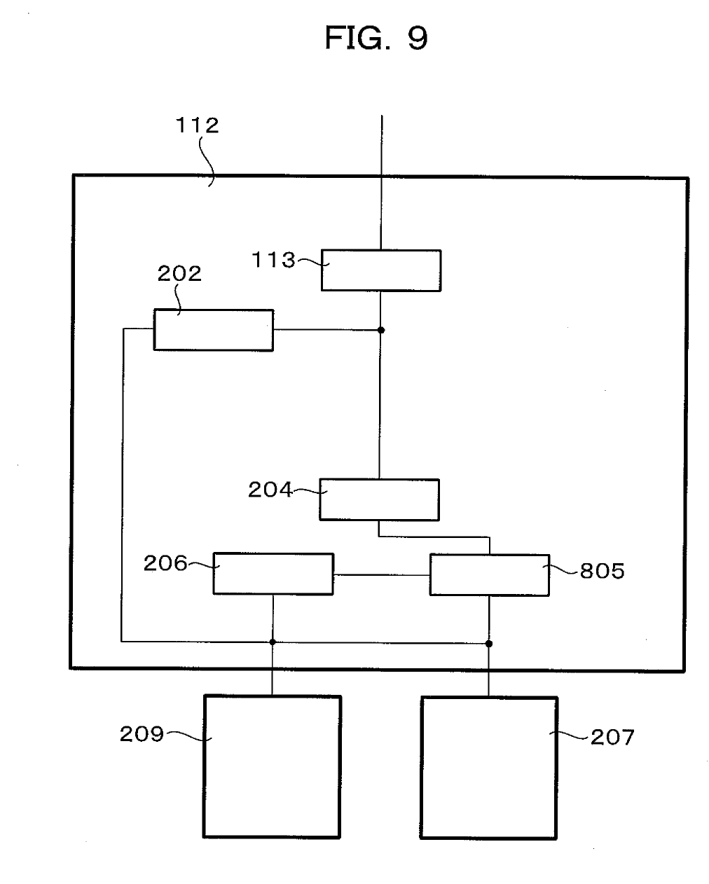

Referring next to FIGS. 9 through 12, a description will be made about a control computer in the plasma processing system according to the second embodiment will be described. As illustrated in FIG. 9, the control computer 112 is provided with a processing parameter acquisition unit 113 for receiving processing parameters, and transmits the thus-acquired processing parameters to a schematization unit 202 for schematizing causal associations among the processing parameters and also to a record unit 204. At this time, the schematization unit 202 schematizes the causal associations among the received processing parameters.

The record unit 204 stores the received values of each processing parameter as history. The history, which the record unit 204 retains, is read by a statistical processing unit 805, and a mode value of the processing parameter in a predetermined period is calculated. At a second comparison unit 206, the thus-calculated mode value is compared with its corresponding preset reference value (second reference value). When the mode value exceeds the reference value, the plasma processing system is determined to be in an abnormal state so that an alarm is produced to an operator by an alarm unit 207. In addition, these analytical results of the control computer 112 are shown on a display unit 209.

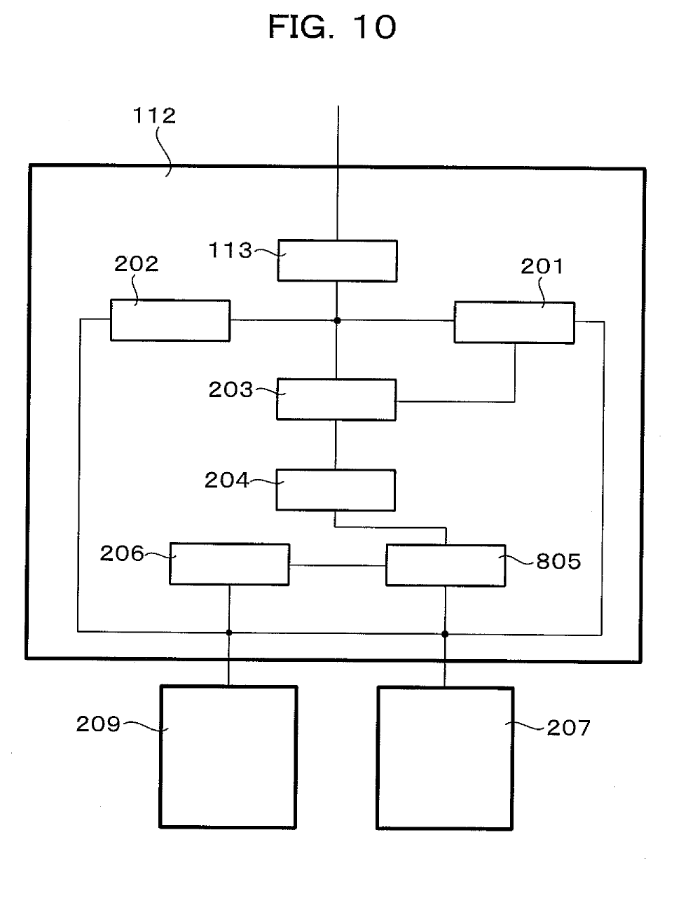

The block diagram of FIG. 10 illustrates an example in which similar to the first embodiment, a model-equation derivation unit 201 and a first comparison unit 203 are arranged. In FIG. 10, the processing parameter acquisition unit 113 transmits the acquired processing parameters to the model-equation derivation unit 201, schematization unit 202 and first comparison unit 203.

From the thus-received processing parameters, the model-equation derivation unit 201 derives a model equation that expresses responses of the group of the processing parameters other than desired one of the processing parameters to the desired processing parameter. The model-equation derivation unit 201 then transmits response values (calculated values), which have been obtained by the thus-derived model equation, to the first comparison unit 203. The first comparison unit 203 compares each processing parameter (found value) so received with its corresponding response value (calculated value) obtained by the model equation, and calculates the difference between them, the absolute value of the difference, the square of the difference, or the like to determine the degree of a divergence of the processing parameter value from its corresponding response value obtained by the model equation. Subsequently, a determination is made based on the degree of the divergence as to whether or not the processing parameter value deviates from the corresponding response value obtained by the model equation. The processing system is determined to be normal when the processing parameter does not deviate, but is determined to be abnormal when the processing parameter deviates.

The above-described determination made by the first comparison unit 203 is transmitted to the record unit 204, and the record unit 204 stores the thus-received determination as history. The history, which the record unit 204 retains, is read by the statistical processing unit 805, and a mode value of outputs from the first comparison unit 203 in the predetermined period is calculated. Subsequent operations are the same as in the case illustrated in FIG. 9.

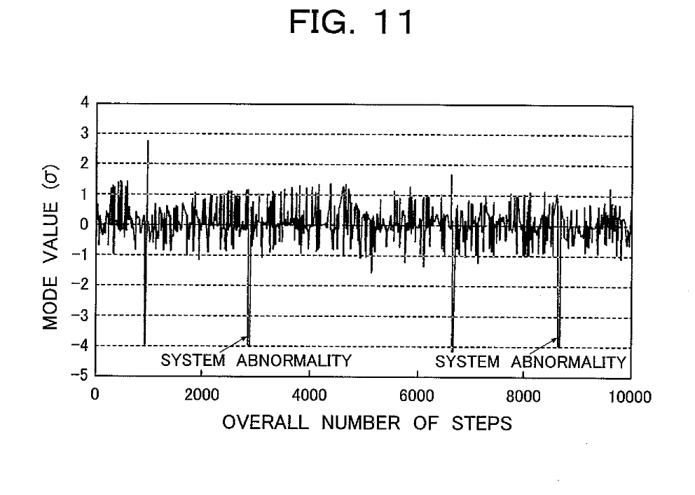

The diagram of FIG. 11 shows variations with time of the mode value of the difference between the calculated value of the desired processing parameter and its corresponding found value as calculated by the first comparison unit 203. Overall numbers of processing steps are plotted along the abscissas, while mode values are plotted along the ordinate. Compared with FIG. 4, the noise is reduced to facilitate the recognition of the situation. This is attributed to the fact that the statistics value of a mode value is a stable index having higher noise durability compared with a statistics value such as an average.

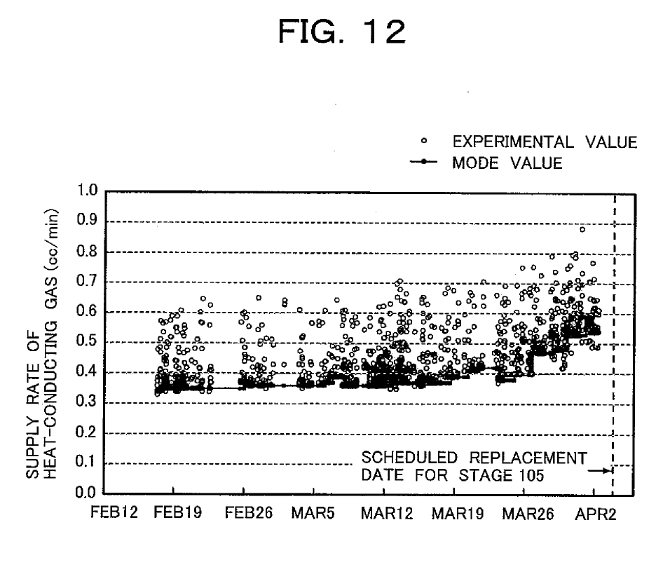

The diagram of FIG. 12 shows variations with time in the supply rate (found value) of heat-conducting gas to be supplied to a stage and variations with time in mode value. It is appreciated that as shown in FIG. 12, the use of a mode value makes it possible to ignore sudden increases in the difference between a found value and its corresponding calculated value and to exactly follow the trend of variations in the difference.

Similar advantageous effects can also be brought about when a minimum value is used in place of the above-described mode value. In the case of a trend that the value of a desired processing parameter progressively decreased over a predetermined period, similar advantageous effects can also be brought about when a maximum value is used in place of the mode value. Further, a statistics value such as a moving average may also be used when noise is sufficiently small, or a statistics value such as a variance or standard deviation may be used when it is desired to deal with noise itself.

As has been described above, the second embodiment of the present invention can produce a high-reliability alarm by using a statistical index such as a mode value, maximum value or minimum value, thereby making it possible to appropriately detect the time of occurrence of an abnormality in the system.

What is claimed is:

1. A plasma processing system comprising:
a processing chamber provided with a plasma generation unit for applying radio-frequency power to supplied processing gas to generate plasma and a stage for holding workpieces thereon, and
a control computer for generating plasma in accordance with preset processing conditions to sequentially apply plasma processing to the workpieces held on said stage and also for sequentially collecting system parameter values each of which represents a state of the plasma processing,
wherein said control computer is provided with:
a record unit for storing, in every predetermined period, a frequency that each of the collected system parameter values deviates from a preset reference value,
an occurrence rate calculation unit for calculating, based on the frequency, an occurrence rate that the each of the system parameter values deviates from the reference value, and
a comparison unit for comparing the occurrence rate with a preset reference value to diagnose a state of said system.

2. A plasma processing system comprising:
a processing chamber provided with a plasma generation unit for applying radio-frequency power to supplied processing gas to generate plasma and a stage for holding workpieces thereon, and
a control computer for generating plasma in accordance with preset processing conditions to sequentially apply plasma processing to the workpieces held on said stage and also for sequentially collecting system parameter values each of which represents a state of the plasma processing,
wherein said control computer is provided with:
a model-equation derivation unit for formulating a correlation of plural parameter values, which indicate a state of said plasma processing system, and outputting a model value of a system parameter of a predetermined system,
a record unit for storing, in every predetermined period, a frequency that each of the collected system parameters of the predetermined system deviates from a reference value set based on the model value of the system parameter outputted by said model-equation derivation unit,
an occurrence rate calculation unit for calculating, based on the frequency, an occurrence rate that the each of the system parameter values deviates from the reference value,
a comparison unit for comparing the occurrence rate with a preset reference value to diagnose a state of said system, and
a display unit for showing a diagram representing causal associations among respective system parameters of the plasma processing system.

3. A plasma processing system comprising:
a processing chamber provided with a plasma generation unit for applying radio-frequency power to supplied processing gas to generate plasma and a stage for holding workpieces thereon, and
a control computer for generating plasma in accordance with preset processing conditions to sequentially apply plasma processing to the workpieces held on said stage and also for sequentially collecting system parameter values each of which represents a state of the plasma processing,
wherein said control computer is provided with:
a record unit for storing the collected system parameter values as history,
a statistical processing unit for calculating, based on the history stored in said record unit, a mode value of a processing parameter in a predetermined period, and
a comparison unit for comparing the mode value calculated by said statistical processing unit with a preset reference value to diagnose a state of said system.

4. A plasma processing system comprising:
a processing chamber provided with a plasma generation unit for applying radio-frequency power to supplied processing gas to generate plasma and a stage for holding workpieces thereon, and
a control computer for generating plasma in accordance with preset processing conditions to sequentially apply plasma processing to the workpieces held on said stage and also for sequentially collecting system parameter values each of which represents a state of the plasma processing,
wherein said control computer is provided with:
a model-equation derivation unit for formulating a correlation of plural parameter values, which indicate a state of said plasma processing system, and outputting a model value of a predetermined system parameter,
a record unit for storing as history, in every predetermined period, deviations of the collected system parameters from the model value of the predetermined system parameter outputted by said model-equation derivation unit,
a statistical processing unit for calculating, based on the history stored in said record unit, a mode value of a deviation of the predetermined system parameter in a predetermined period,
a comparison unit for comparing the mode value calculated by said statistical processing unit with a preset reference value to diagnose a state of said system, and
a display unit for showing a diagram representing causal associations among respective system parameters of the plasma processing system.

5. The plasma processing system according to claim 2 or claim 4, wherein said display unit shows each system parameter value, which deviates from its corresponding reference value, in a color different from system parameter values which do not deviate from their corresponding reference values.

6. The plasma processing system according to claim 4, wherein a maximum value or minimum value is used in place of the mode value.
